(19) United States
(12) Patent Application Publication
(10) Pub. No.: US 2005/0248471 A1
(43) Pub. Date: Nov. 10, 2005

(54) Method and apparatus for displaying a time-varying code to a handheld terminal, and method and apparatus for approval authentication processing by using the same

(75) Inventor: Junghee Ryu, Seoul (KR)

Correspondence Address: SHINJYU GLOBAL IP COUNSELORS, LLP, 1233 20TH STREET, NW, SUITE 700, WASHINGTON, DC, 20036-2680, US

(73) Assignee: ICONLAB, INC, SEOUL (KR)

(21) Appl. No.: 10/519,480

(22) PCT Filed: Jul. 3, 2003
(86) PCT No.: PCT/KR03/01314

§ 371 Date: Dec. 30, 2004

(30) Foreign Application Priority Data
Jul. 3, 2002 (KR) 10-2002-0038269

(51) Int. Cl. H03M 1/22

(52) U.S. Cl. 341/1

(57) ABSTRACT

Method and apparatus for displaying a time-varying code to a handheld terminal, and method and apparatus for approval and authentication processing by using the same, which is able to read in machine and which is the one dimensional and second dimensional code that recording a prescribed information, which is the shape, position, the tone of color, light and darkness of code pattern or the combination of that variable in accordance with time, which is the time-varying code for authentication that is able to read in machine in spite of the variation of code pattern, is provided. Also, the system for reading and displaying in the handheld terminal a time-varying code for authentication, a time-varying code system for authentication that is including the server, handheld terminal and reading machine, is provided.

### BACKGROUND OF THE INVENTION

1. Field of the Invention

The present invention relates to a method and an apparatus for displaying barcode in a handheld terminal. In particular, the invention is directed to the method and the apparatus for displaying time-variant code and to the method and the apparatus for payment and authentication using the same.

2. Background of the Related Art

Recently, a lot of handheld terminals including a cellular phone are popularized and telecommunication technologies are also developing rapidly. In these circumstances, it is considered that automatic banking apparatuses such as ATM, CD and CDP and next-generational paying means that can be operated by the handheld terminals are also popularized.

On the other hand, barcode has been generally used for management of logistics, distribution of products and the like.

In general, barcode is categorized into one-dimensional barcode and two-dimensional barcode. The one-dimensional barcode is expressed one-dimensionally by combination of white bars and black bars which have different thickness one another. In the two-dimensional barcode, the unit of contained information is a form of matrix. However, it is easy to copy the conventional barcode. Thus, the conventional barcode is not suitable for paying means.

It has become very convenient since a person can achieve banking and purchasing and get discount coupon by handheld terminal device. However, the barcode payment system through a handheld terminal is not popularized because of the security problem such as copy and/or illegal generation.

FIG. 1 shows a block diagram of an apparatus for displaying barcode for authentication in a conventional handheld terminal. In particular, the diagram relates to the embodiment wherein the authentication barcode is displayed in a mobile handset, a representative handheld terminal. As shown in FIG. 1, mobile handset (100) comprises a communication terminal module and a barcode reading unit (113). The communication terminal module comprises an antenna (119) for receiving and transmitting communication signal, a frequency processing unit (101, 103) for processing received or transmitted communication signal from antenna (119) of mobile handset (100), an A/D converter (105), a D/A converter (107), a control unit (125) for controlling the components of mobile handset (100), a displaying unit (109) such as LCD for visually displaying the operating state of mobile handset (100) and/or the processing state of various functions, a memory (117) that has a program for operating mobile handset (100), a program for barcode and data relating to the barcode, which are recorded therein, a power unit (111) for supplying electric power necessary for mobile handset (100).

In general, memory (117) can be EEPROM, SRAM, flash ROM and the like. The basic program for operating mobile handset (100) is recorded in EEPROM. Temporary data that is generated during the operation of mobile handset (100) is recorded in SRAM. Semi-permanent data such as telephone number is recorded in flash ROM.

Barcode reading unit (113) for recognizing barcode and reading the barcode is mounted in one side of mobile handset (100). The reading unit comprises a sensor for recognizing a barcode and a converter for converting the analog signal that is generated by the sensor into digital signal. The information that is generated by barcode reading unit (113) as a result of reading a barcode containing the information relating to a product and/or discount coupon, is sent to control unit (125) and is recorded in memory (117)

FIG. 2 shows a code that can be displayed in a conventional handheld terminal. The first code shown in FIG. 2 is a one-dimensional barcode (201). One-dimensional barcode is expressed one-dimensionally by combination of white bars and black bars, which have different thickness one another. The one-dimensional barcode can contain information such as alphabet, number and character. The one-dimensional barcode comprises UPO (Universal Product Code), EAN (European Article Numbering), code 39, I2/5 (Interleaved 2 of 5) code 93, code 128, Plesssey code, code 11, 2 of 5 and the like.

Two-dimensional barcode means a form of barcode wherein data is arrayed in vertical axis (X-axis) and horizontal axis (Y-axis). Compared with the one-dimensional barcode containing the information relating to alphabet, number and limited characters, the two-dimensional barcode can even contain the information relating to Korean characters and Chinese characters and picture. Further, the two-dimensional barcode can contain a lot of data compared with the one-dimensional barcode. In terms of printing and reading, the two-dimensional barcode is superior to the one-dimensional barcode. It is most important difference that the error of two-dimensional barcode can be corrected while it is impossible in the one-dimensional barcode.

PDF-417 code (203) which was created by Symbol Technologies Inc. in 1989 is a two-dimensional barcode wherein the length and the height of the symbol are variant. PDF-417 code is suitable for handheld data file since it can contain large number of data and since it has detecting function of data error and correcting function thereof. PDF-417 code can be recognized by a conventional linear laser scanner, laster laser scanner, linear CC scanner, and 2D CCD scanner. One symbol character comprises a combination of four bars and four spaces. The name of PDF-417 was originated from the fact that the length of one symbol is 17 modules (176X). PDF-417 code has advantages of being recognized by various conventional scanners and of being open system. Therefore, any user can apply the code in many fields easily and conveniently.

QR code (205) which was created by Nippondenso Inc. of Japan in 1994 is 2D code of matrix type. QR code stands for Quick Response Code. The code is created so as to be suitably applied to the field requiring quick reading such as logistics and factory automation. QR code has two small cutout symbols in its left upper side and right upper side and down side, which make it possible to quickly recognize the symbol direction and to quickly read the symbol. QR code employs Reed-Solomon algorithm for detecting data error and correcting the error in three stages. First stage can detect and correct the error by 7%; second stage can detect and correct the error by 15%; and third stage can detect and correct the error by 30%.

Color code (207) means a code wherein source information is codified using color information. The color code uses the combination of colors of red, green, blue and black in 25 square areas, each of which is 5 mm by 5 mm. The color code is different from the conventional barcode in that general PC camera is used for reading the code. The read-out value retrieves information stored in a server through the Internet. The color code can contain nearly indefinite information since it retrieves information from the Internet server, compared with the conventional barcode containing the limited information regarding manufacturing date and the like.

Data matrix (209) is a matrix type code that was created in 1989. It was developed for increasing the amount of data that can be contained in a symbol while Vericode emphasizes security. The side of the symbol can have the length of between 0.01 inch and 14 inch. One symbol can contain maximum of 2334 alphanumeric characters. Five hundred numbers can be contained in a square of 1 inch by 1 inch by use of a dot-matrix printer. Five hundred ASCII characters can be contained in a square of 1.4 inch by 1.4 inch. Data Matrix can be categorized into two symbols of ECC 000-14- and ECC 200 according to error checking and correction algorithm. ECC 000-140 employs convolutional error checking and correction algorithm while ECC 200 employs Reed-Solomon algorithm.

Aside by the above codes, the two-dimensional code comprises iClickGo, Code 49, Code 16K, Maxi code, Code One, Veri code, CodaBlack (MCL-2D), ArrayTag, Philips Dot code, Softstrip code and the like.

In the conventional 1D or 2D codes, various formats can be categorized according to the pattern, position, tone and brightness. However, the barcodes has a problem of authentication security since a third party can copy the pattern of the barcode.

Further, the data-capacity of the conventional barcode depends on the unit area of the code, thereby limiting the capacity, since the barcode is static. In order to increase the data-capacity of the barcode, the integrity of the unit area should increase. However, the conventional barcode reader may have difficulty of reading the barcode of high integrity.

FIG. 3 shows a service flow based on a barcode reader for reading the conventional barcode.

A user logins a mobile carrier server (301) and downloads a barcode into its mobile handset (303). The downloaded barcode is stored in recording medium of user's mobile handset (303). The LCD of mobile handset (303) displays the barcode and the barcode is read by barcode reader (305) at a store. The server of the mobile carrier compares the barcode with the data stored in its DB for checking validity. If the authentication is accomplished, the user can purchase a product corresponding to the barcode.

However, the downloaded barcode can be visually copied by a third party. Further, a third party can generate a barcode illegally by use of a generating tool since the conventional barcode has open specification. For example, a third party can copy the barcode which is displayed in the user's mobile handset (303), by scanning the code. Alternatively, a third party who is not a valid member of the service generates the same code as the true code by use of an open tool.

### SUMMARY OF THE INVENTION

The object of the invention is to provide a safe and variously-applicable barcode display apparatus and a method for resolving the above problems of the conventional barcode such as copying and illegal generation.

Another object of the invention is to provide a time-variant barcode that has large data-capacity, which has patterns that vary according to the time, in order to resolve the limitation of data-capacity of the conventional barcode wherein data-capacity depends upon the unit area of the barcode.

### BRIEF DESCRIPTION OF THE DRAWINGS

FIG. 1 shows a block diagram of barcode displaying apparatus of the conventional handheld terminal.

FIG. 2 shows a code that is displayed in the conventional handheld terminal.

FIG. 3 shows a service flow based on the conventional barcode reader.

FIG. 4 shows a pattern variation of a time-variant code according to one embodiment of the present invention.

FIG. 5 shows a system displaying an authentication time-variant code in a handheld terminal according to the present invention.

FIG. 6 shows a block diagram of typical handheld terminal for displaying the authentication time-variant code according to the present invention.

FIG. 7 shows a block diagram of a reader for reading the authentication time-variant code according to the present invention.

FIG. 8 shows a flow chart of process for reading the authentication time-variant code according to the present invention, using the conventional static code reader.

FIG. 9 shows a flow chart of process for generating time-variant code in a server.

FIG. 10 shows a flow chart of process for generating time-variant code according to the identification-information transmitted from the server, in a handheld terminal.

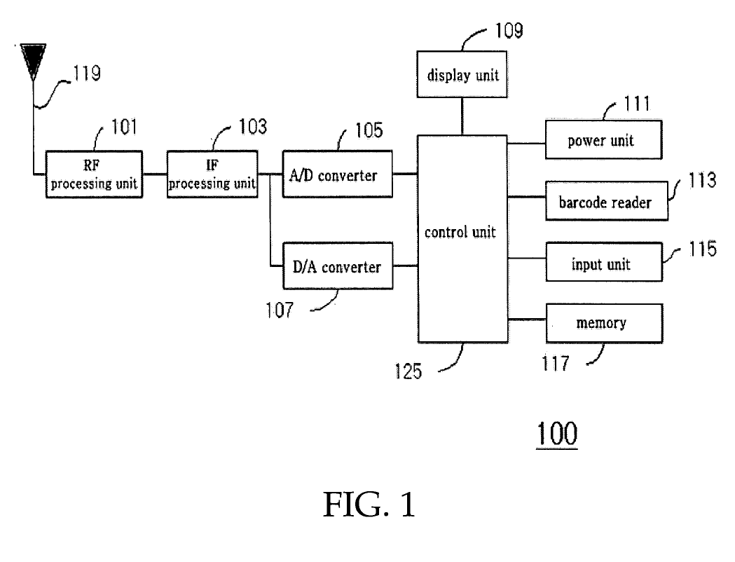

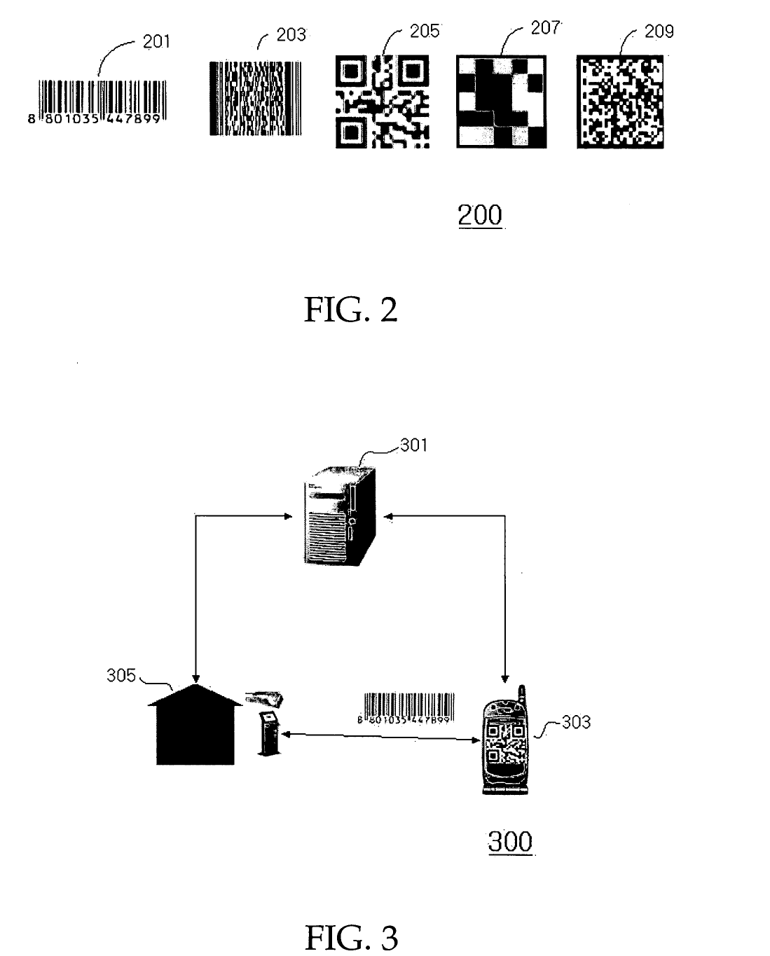

### DETAILED DESCRIPTION OF THE PREFERRED EMBODIMENT

In the following, the embodiments of the present invention will be described in detail with reference to the accompanied drawings.

The apparatus and the method for displaying the authentication time-variant code according to the present invention

The embodiments of the authentication time-variant code will be described.

Embodiments According to the Static Patterns

One-dimensional time-variant code will be described.

The one-dimensional time-variant code may comprise a one-dimensional time-variant code of position-variation wherein the pattern position of one-dimensional code varies according to time; a one-dimensional time-variant code of tone-variation wherein the pattern tone of one-dimensional code varies according to time; and a one-dimensional time-variant code of brightness-variation wherein the pattern brightness of one-dimensional code varies according to time. Alternatively, the combination of position, tone and brightness of the pattern may vary according to time.

The static pattern of one-dimensional code may comprise UPO (Universal Product Code), EAN (European Article Numbering) code 39, I2/5 (Interleaved 2 of 5), code 93, code 128, Plessey code, code 11, 2 of 5 code. In particular, the thickness and space of UPC barcode strip may vary according to time.

Two-dimensional time-variant code will be described.

The two-dimensional time-variant code may comprise a two-dimensional time-variant code of shape-variation wherein the pattern shape of two-dimensional code varies according to time; a two-dimensional time-variant code of position-variation wherein the pattern position of two-dimensional code varies according to time; a two-dimensional time-variant code of tone-variation wherein the pattern tone of two-dimensional code varies according to time; and a two-dimensional time-variant code of brightness-variation wherein the pattern brightness of two-dimensional code varies according to time. Alternatively, the combination of shape, position, tone and brightness of the pattern may vary according to time.

The static pattern of two-dimensional code may comprise PDF-417 code, QR code, Color code, iClickGo, Data Matrix, Code 49, Code 16K, Maxi code, Code One, Veri code, CodaBlack (MCL-2D), ArrayTag, Phillips Dot code, Softstrip code and the like. In particular, the color of color cell may vary according to time when the Color code is used.

Embodiments According to Time-Variant Type

Combination time-variant code (random time-variant code)

According to one embodiment of the present invention, the static pattern randomly varies according to time. However, the number of static pattern that varies randomly has limitation and the combination of the limited number of static pattern forms a time-variant code.

For example, if a time-variant code is defined by static patterns A, B and C, the time-variant code is displayed by the random selection of the patterns. A decoder monitors time-variant code for a predetermined period and decodes source information based on the extracted three static patterns.

Circulating Time-Variant Code

According to another embodiment of the present invention, static patterns circulate with a certain order according to time.

The circulating time-variant code differs from the combination time-variant code in that the time-variant code is formed with a certain order according to time.

For example, if a time-variant code is defined by static patterns A, B and C, the time-variant code may be displayed by ABC and ACB according to a certain repetition order of the three static patterns. A decoder monitors for a predetermined period and decodes source information based on the extracted three static patterns and the circulating order information.

Time-Modulation Code

According to the other embodiment of the present invention, a time-modulation code is provided which uses variation of time-variant timing when static patterns varies according to time.

For example, if a time-variant code is defined by static patterns A and B and if the time duration for the change between A and B is defined by a and b each other, the time-variant code can be generated by the combination of the static patterns A and B and the information of time duration of a and b. A decoder monitors the time-variant code for a predetermined period and decodes source information based on the extracted static patterns and the information of time duration of change between the static patterns.

Error detection and code information recording capacity of time-variant code for recognizing pattern

Error detection of time-variant code for recognizing pattern

The time-variant using conventional color code has a problem that the difficulty of recognizing color may rise depending upon intensity of illumination and printing quality. Thus, error detecting code should be used. However, the time-variant code according to the present invention has much less error than the conventional color code. Further, pattern-recognition module can use various formats simultaneously. In addition, quick recognition is possible with less error code and error detection is also easily achieved.

The conventional barcode has a problem that code is wasted and the time for recognizing the code since the error detection code occupies large information-containing capacity.

The time-variant code for recognizing pattern of the present embodiment uses the error detection type and error detection code simultaneously, thereby saving number of codes and making it possible to raise probability of recognition.

Information-containing capacity of time-variant code for recognizing pattern

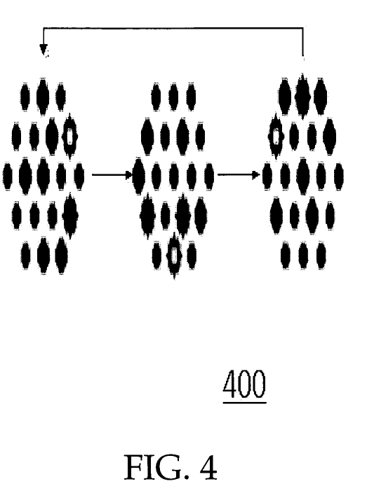

FIG. 4 shows a pattern variation of time-variant code according to an embodiment of time-variant code.

The time-variant code shown in FIG. 4 has three sizes of dots and forms a honey comb. This type is called I₃C₁₈. “I” means the size of dot and “C” means the number of total dots.

The pattern of I₃C₁₈ type can have combination of 3¹⁸ . That is, the time-variant code has large data capacity compared with the conventional barcode that has limitation of data capacity since the information depends upon the area of its code.

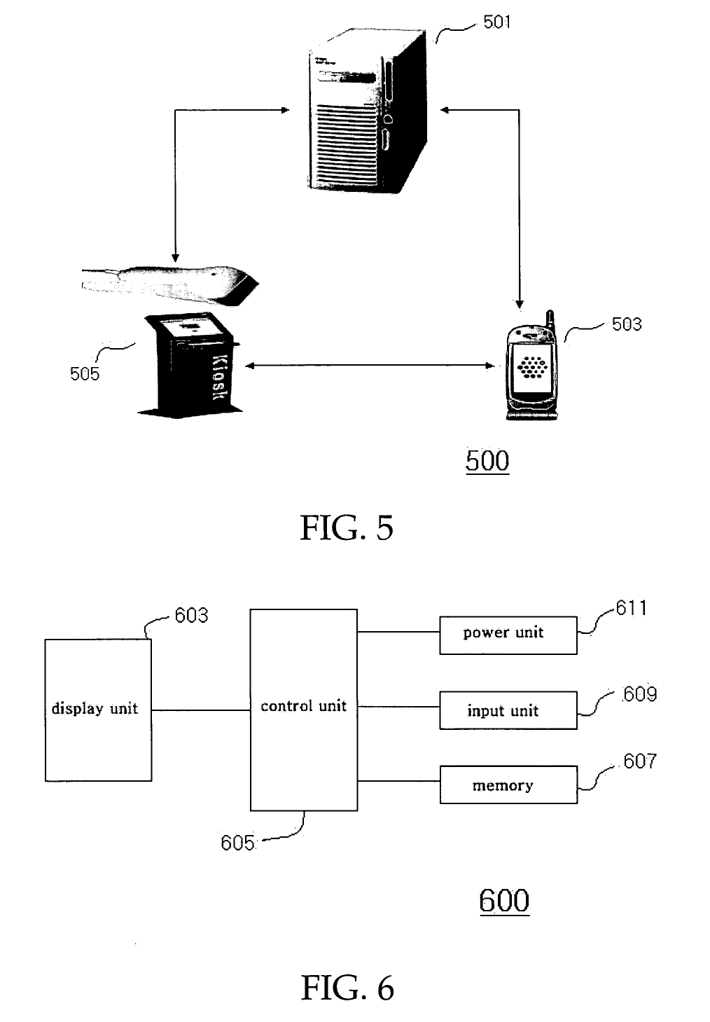

FIG. 5 shows a system for displaying authentication time-variant code according to the present invention in handheld terminal.

The system comprises a server, a handheld terminal and a barcode reader.

[Server]

Server (501) generates a time-variant code upon receiving request from handheld terminal (503); decodes the time-variant code that is generated or read by handheld terminal (503); and authenticates the user after decoding process.

The constitution of server (501) varies depending upon whether the generation or decoding of the time-variant code is achieved in the server or the handheld terminal. The server may have further components for coupling the conventional application systems.

[Handheld Terminal (503)]

Handheld terminal (503) of the present invention means a portable device that has display means for displaying barcode.

A handheld terminal having display function falls within the scope of the handheld terminal of the present invention. The terminal includes a handheld terminal having wireless mobile communication and information-processing function. The representative terminals include mobile handset, PDA and laptop computer having wireless LAN. Other devices having communication function and information-processing function are also included in the terminal of the present invention.

FIG. 6 shows a block diagram of a handheld terminal for displaying authentication time-variant code according to the present invention.

Display unit (603) may be LCD and visually displays operation state and processing state of handheld terminal function. In particular, the display unit visually shows authentication time-variant code.

Control unit (605) controls all functions of receiving authentication time-variant code, temporarily storing authentication time-variant code and displaying authentication time-variant code upon request from a user.

Memory (607) stores data relating to received authentication time-variant code.

Input unit (609) inputs a predetermined command from the user.

Power unit (611) supplies electric power necessary for operating the handheld terminal.

It is preferred that the handheld terminal is provided with graphical user interface.

A handheld terminal having transceiving unit may include mobile handset, PDA and laptop computer having wireless LAN. The transceiving unit comprises an antenna for transmitting and/or receiving signal, A/D and D/A converter so as to carry communication function and to receive authentication time-variant code.

Mobile Phone

A mobile phone means a communication device that communicates with a fixed-line phone and a mobile phone through local bases within wireless zone. Recently, the mobile phone such as cellular phone and PCS phone is popularized which has functions of voice calling, short message transmission, image transmission and the Internet connection using WAP (Wireless Application Protocol). Further, the mobile phone such as IMT-2000 and CDMA-2000 will be commercialized. The mobile phone includes all of the above phones.

PDA

PDA is a handheld device having wireless communication function and data processing function. It is also called personal data processor or personal handheld communication terminal. PDA has functions of managing personal schedule, managing personal information using electronic pen or recognition of handwriting, searching imbedded dictionary or manual, communicating using email, fax, wireless calling and mobile phone message.

Computer

A computer means a device that receives information; processes the information according to a predetermined order; and provides the processed results. In this embodiment, it means a handheld computer having communicating function, for example, a laptop computer having wireless LAN.

Time-Variant Code Reader (505)

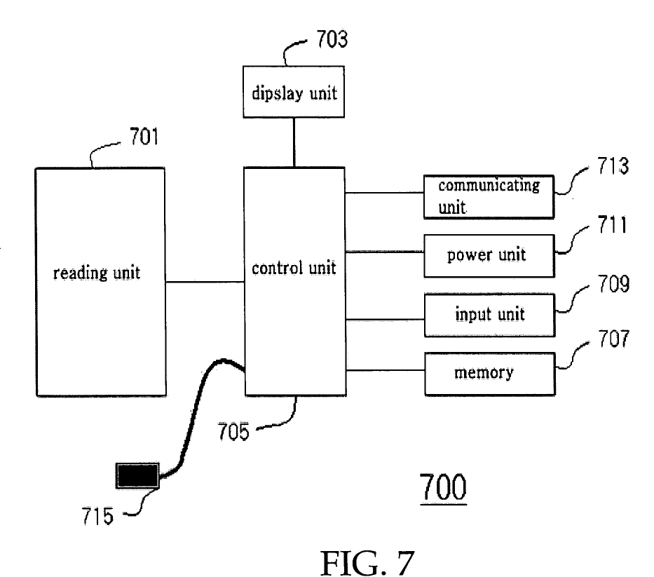

A time-variant code reader is a device that reads server-generating time-variant code displayed in a user's handheld terminal. The constitution of the time-variant code will be described in the following with reference to FIG. 7.

FIG. 7 shows a block diagram of the time-variant reader for reading authentication time-variant code according to an embodiment of the present invention.

Display unit (703) such as LCD visually displays the operating state or the processing state of function of the reader and visually displays the authentication time-variant code.

Control unit (705) controls functions of receiving authentication time-variant code, temporarily storing the authentication time-variant code and displaying the authentication time-variant code upon user's request.

Memory (707) stores data relating to received authentication time-variant code.

Input unit (709) has functions of inputting a predetermined command from the user, into the barcode reader.

Power unit (711) supplies electric power necessary for operation of the barcode reader.

Communication unit (713) transmits the information of the read barcode to the server and receives authenticating signal.

Connection unit (715) installed separately from the barcode reader acts as a role of inputting codified information corresponding to the time-variant code to the time-variant code reader. Connection unit (715) may include USB port, IEEE 1394, optical cable coaxial cable, SCSI, IEEE 802.12, IDE and Bluetooth and the like.

Reading unit (701) may be a conventional barcode reading means.

In general, reading unit (701) comprises a sensor or scanner for recognizing a time-variant code and a converter for analog signal from the sensor or scanner into digital signal. Electronic signal is generated according to the intensity of light reflected from the input medium where a time-variant code is displayed. The signal can operate logic circuit and the time-variant code is converted into computer code. Two-dimensional barcode reader divides two-dimensional barcode into electronic bits and stores in a computer for reproducing the code.

According to another embodiment of the present invention, reading means (701) exclusive only for time-variant code can be used. For example, CCD camera and smart camera can be used.

CCD camera inputs time-variant code to be read into time-variant code reader. CCD is widely used for solid picturing device (image sensor) of digital camera and various video camera since it can transmit analog signal according to the size of charge. The time-variant code of the embodiment is recognized by CCD camera while the conventional barcode having static pattern is recognizable by optical sensor.

Smart camera has imbedded processor so as to analyze the image as well as simply process the image. Further, additional function can be achieved by interfacing with attached terminal.

Reading the time-variant code according to the present invention is achieved by image processing module, image analyzing module and interface module.

Image processing module processes the image recognized by reading unit (701) into the form that can be analyzed. Image processing module can be achieved by reading unit (701) and control unit.

Image analyzing module analyzes the image processed by the image processing module. The image analyzing module can be achieved by the control unit of the time-variant code reader. Alternatively, it can be achieved outside of the time-variant code reader. If the smart camera is used for the time-variant code reader, the image analyzing is achieved within the time-variant code reader.

The interface module interfaces the processed image or the analyzed image with outer devices.

The reader can be manufactured in the form attachable to a handheld terminal.

The reader module attached to a handheld terminal includes an embodiment wherein a server carries all of decoding processes; an embodiment wherein the server carries some of decoding processes and the handheld terminal carries the other decoding processes; and an embodiment wherein the handheld terminal carries all of decoding processes.

In the embodiment wherein a server carries all of decoding processes, the reading module attached to the handheld terminal comprises a reading lens, a sensor and a control unit for picturing image.

In the latter two embodiments, the reading module attached to the handheld terminal comprises an image processing unit, an image analyzing unit and an interface unit. The image processing unit comprises a reading lens and a control unit for picturing image. The image analyzing unit comprises memory, micom and ROM. The interface unit comprises handheld terminal interface.

The reading module as described in the above can be manufactured in a form attachable to a handheld terminal. Alternatively, it can be imbedded into the handheld terminal.

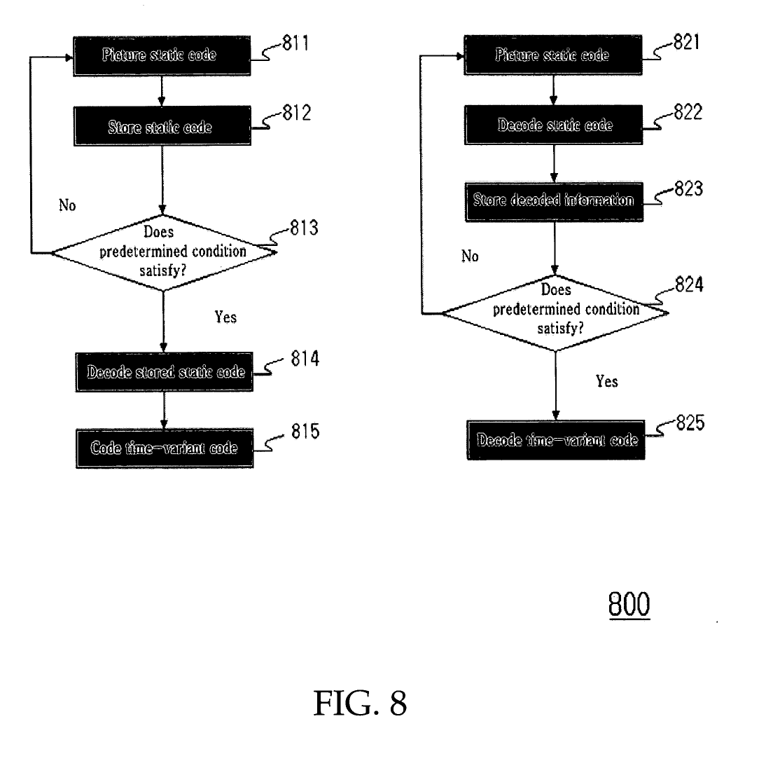

FIG. 8 shows a flow chart of reading the time-variant code according to the present invention using the conventional static code reader.

It is possible to make a reader for reading the time-variant code using the conventional static code reader.

The conventional static code reader comprises an image processing unit and an interface unit.

In order to make a time-variant code reader, a time-variant code processing unit is added to the interface unit of the conventional static code reader. The time-variant code processing unit comprises memory for storing the static code and an analyzing unit of the time-variant code.

There are two method for reading the authentication time-variant code according to the present invention using the conventional static code reader.

First, a camera or an optical sensor pictures the static code (811).

The static code is stored in memory (812).

The control unit determines whether the stored static code satisfies the condition for decoding (813). If it is determined that the condition is not satisfied, the static picture of the time-variant code is stored continuously in memory.

If it is determined that the condition is satisfied, the stored static code is decoded (814).

If the decoding is completed, the time-variant code decoding is carried (815). In the above processes, the time-variant code is read.

Alternatively, the decoding process of the static code is carried before the process of storing the decoded information.

The static code is pictured by a camera or an optical sensor (821).

The pictured static code is decoded (822).

The decode information of the static code is stored in the memory (823).

The control unit determines whether the stored decoded information satisfies the condition for decoding (824). If it is determined that the condition is not satisfied, the static picture of the time-variant code is stored continuously in memory.

If it is determined that the condition is satisfied, the stored static code is decoded (825). In the above processes, the time-variant code is read.

Embodiments According to Transmission Type

Real-time transmission of time-variant information

This means that the authentication time-variant code is transmitted to the server real-time upon variation's occurring. The read barcode information is continuously transmitted to the server without reading the barcode using CCD camera.

Collective Transmission of Time-Variant Information

This means that the variation of the authentication time-variant code is stored, and thereafter the entire variation pattern is collectively transmitted. In this embodiment, CCD camera transmits the time-variant code with a barcode reader which reads the time-variant code collectively and thereafter transmits it to a server.

Embodiments According to Code Generating Type

Upon request from a user, source information is transmitted to a server which generates a time-variant code. Alternatively, a user's handheld terminal may generate a time-variant code using the source information.

Embodiments wherein a server generates a time-variant code

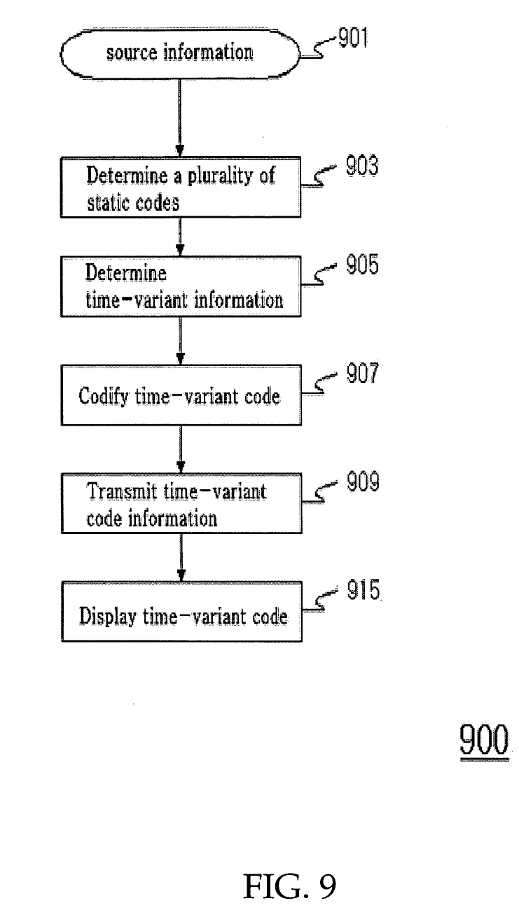

FIG. 9 shows a flow chart of a server's generating a time-variant code.

The server carries the following processes for codifying source information (901) into a time-variant code.

A plurality of static codes are determined (903).

It is determined whether time-variant pattern is combination time-variation or circulating time-variation (905).

After the time-variation information is determined, the time-variant code is codified (907).

The codified time-variant information (static code information and time-variant information) is forwarded to a handheld terminal (909).

The handheld terminal displays the forwarded time-variant code (915).

Embodiment wherein a handheld terminal generates a time-variant code according to the transmitted identification information

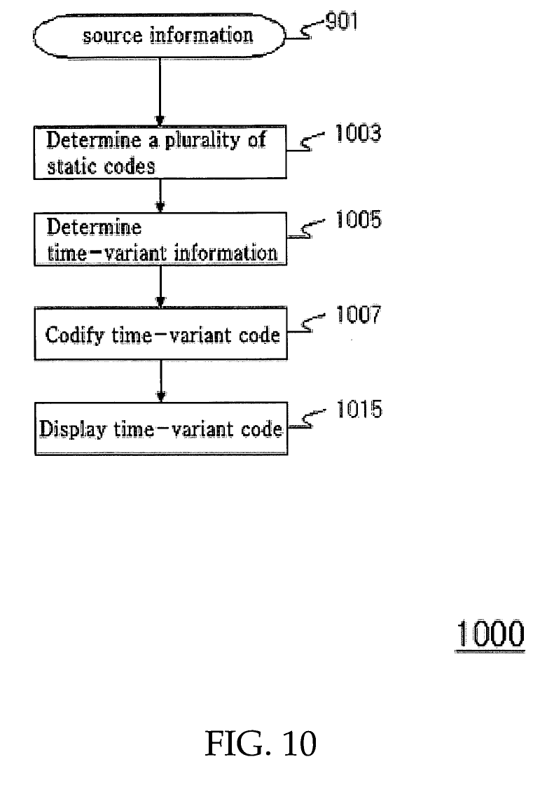

FIG. 10 shows a flow chart of a handheld terminal's generating a time-variant code according to the transmitted identification information from a server.

The handheld terminal carries the following steps for codifying the transmitted source information (901) into a time-variant code.

A plurality of static codes are determined (1003).

It is determined whether time-variant pattern is combination time-variation or circulating time-variation (1005).

The handheld terminal displays the codified time-variant code (1015).

Identification-information transmission between handheld terminals by time-variant code

It is possible that the identification-information expressed by time-variant code is transmitted between handheld terminals by use of short message service or image message service.

In this embodiment, a first handheld terminal has a function of time-variant code display and a second handheld terminal has the time-variant code reading module as described in the above, which is attached thereto or imbedded therein. The identification-information expressed by time-variant code is read and decoded by the other handheld terminal.

Embodiments According to Code Decoding Type

The decoding process for reading a time-variant code will be described. Upon request of time-variant code reading, the time-variant code is sent to a server which decodes the code. It is also possible that a time-variant code reader or other independent device decodes the code.

Decoding of the time-variant code sent to server

The image of the time-variant code is transmitted to the server.

The server decodes the transmitted time-variant code.

Time-variant information is determined from the decoded time-variant code and a plurality of static codes are read. Thereafter, the source information is extracted.

The server re-sends the source information of the time-variant code.

Decoding in Independent Device

In this embodiment, the independent device has an image analyzing module for reading a time-variant code.

Upon receiving time-variant code from a user, the independent device inputs the time-variant code and decodes it.

The time-variant information is determined from the decoded time-variant code and a plurality of static codes are read. Thereafter, the source information is extracted.

The independent device may include a handheld terminal, a kiosk, a reader for exclusive use and a computer.

Store

In the event that a purchaser presents in a store a time-variant code expressing purchasing coupon or discount coupon, a time-variant code reader of the store may read the time-variant code and directly decode.

Kiosk

A kiosk defined in information technology means a small structure for expressing information for passenger and has a computer and a display monitor. More refined kiosk operates in communicating way with a user and has touch screen. It can reproduce sound and moving picture. In a simple kiosk, the expressed character may have enough size to attract passenger's attention and tool bar of web-browser may be removed for kiosk monitor mode. The kiosk presentation can be made so that a series of pages are repeated or so that interaction with user and search is possible. If time-variant code decoding function is added to the kiosk, the time-variant code can be recognized and read out in the kiosk without being sent to a server.

Reader with Exclusive Use

A reader with exclusive use that can read the conventional one-dimensional barcode and two-dimensional barcode as well as the time-variant code, has advantages that recognizing speed is higher than the other independent device. The reader does not need additional hardware or software. Further, the reader has connection means for directly connecting to a conventional POS system and integrated CAT (Card Authentication Terminal) without any design change.

Computer

A camera module attached to a computer can carry decoding of time-variant code. In this constitution, the computer reads out the time-variant code from a continuous set of static codes inputted from the camera module and decodes them.

The decoding as described in the above is carried by a computer program that is recorded in a recording medium.

### INDUSTRIAL APPLICABILITY

The time-variant code can increase visual security continuously by varying codes with various ways. Thus, it can resolve the problem of copying and illegally generating barcodes.

Further, the information-capacity can increase indefinitely according to the number of codes varying with time, thereby making it possible to enlarging the capacity of storing information.

1. An authentication time-variant code which can be read out by a machine, said time-variant code being one-dimensional and two-dimensional code,
wherein shape, position, tone, brightness of code pattern or combination of the shape, position, tone, brightness of the code pattern vary according to time and wherein a predetermined information is contained in code pattern variation.

2. The authentication time-variant code of claim 1, wherein a limited numbers of static patterns vary randomly.

3. The authentication time-variant code of claim 1, wherein static patterns vary with order as time goes.

4. The authentication time-variant code of claim 1, using change of time-variation timing when static patterns vary.

5. A system for displaying authentication time-variant code and reading out the code, comprising:
a handheld terminal having a displaying apparatus;
a reader for reading out time-variant code displayed in the handheld terminal, said code being generated in said server.

6. The system of claim 5, wherein said server couples to application of conventional barcode system.

7. The system of claim 5, wherein said handheld terminal comprises communication module and information processing module.

8. The system of claim 5, further comprising graphic user interface environment.

9. The system of claim 5, wherein said reader comprises a display unit for visually displaying processing state of functions and visually displaying said authentication code;
a control unit for controlling functions of receiving the authentication code, temporarily storing the authentication code and displaying the authentication code;
a memory for storing data relating to the authentication code;
an input unit for inputting user's commands to a reading unit;
a power unit for supplying electric power necessary for operating the reading unit;
a communication unit for transmitting the read out information of the reading unit and receiving authenticating signal;
a reading unit having a sensor for recognizing the code or a scanner and a converter for converting analog recognized signal from the sensor or scanner into digital signal.

10. The system of claim 9, wherein said reading unit comprising a reading unit for exclusive use of time-variant code.

11. The system of claim 9, further comprising a connection means for inputting information corresponding to the time-variant code, in addition to said reading unit.

12. A method for reading authentication time-variant code, comprising:
a step of picturing static pattern of the time-variant code using a camera or an optical sensor;
a step of storing the pictured static code in memory;
a decoding-condition determining step of determining whether the number of the stored static codes satisfies a predetermined condition for decoding said time-variant code;
a static code decoding step of decoding the stored static code if the number of the static codes satisfies the predetermined condition for decoding said time-variant code;
a time-variant code decoding step of decoding the time-variant code after said static code decoding step; and
a time-variant code reading step of reading the decoded time-variant code.

13. A method for reading authentication time-variant code, comprising:
a static code picturing step of picturing the static pattern of the time-variant code using a camera or an optical sensor;
a static code decoding step of decoding the pictured static code;
a decoded information storing step of storing the decoded information of the static code in memory;
a decoding condition determining step of determining whether the decoding information of the stored static code satisfies a predetermined condition for decoding the time-variant code;
a time-variant code decoding step of decoding the time-variant code if the number of the decoded information of the static codes satisfies the predetermined condition for decoding said time-variant code;
a time-variant code reading step of reading the decoded time-variant code.

14. A method for displaying an authentication time-variant code and reading the code, comprising:
a step of determining a plurality of static codes, a step of determining the type of the time-variant code and a step of codifying the time-variant code, in order to generate the time-variant code in a server; and
a step of transmitting the static code information of the codified time-variant code and the type of time-variant pattern.

15. A method for displaying an authentication time-variant code and reading the code, comprising:
a step of receiving source information;
a step of determining a plurality of static codes;
a step of determining a type of the time-variant pattern; and
a step of codifying the time-variant code.

16. A method for displaying an authentication time-variant code and reading the code, comprising:
a decoding step of decoding code image receiving from a server;
a source information extracting step of determining time-variant information through the decoded time-variant code; and
a re-sending step of server's re-sending the source information of the time-variant code.

17. The method of claim 16, wherein if independent apparatus has image analyzing module, the independent apparatus carries decoding step and source information extracting step without transmitting the image of the time-variant code to the server
